(19) United States
(12) Patent Application Publication
(10) Pub. No.: US 2025/0263837 A1
(43) Pub. Date: Aug. 21, 2025

(54) FLARED SHUTTER LINER FOR CHEMICAL VAPOR DEPOSITION SYSTEM

(71) Applicant: VEECO INSTRUMENTS INC., Plainview, NY (US)

(72) Inventors: Sandeep Krishnan, Princeton Junction, NJ (US); Bojan Mitrovic, Friedberg (DE); Scott Burfeind, Glen Gardner, NJ (US); Eric Armour, Pennington, NJ (US); Andrew Hanser, Morristown, NJ (US); Gerald O'Hara, Doylestown, PA (US); Alexander Gurary, Bridgewater, NJ (US); Alexander Lerner, San Jose, CA (US); Jeffrey Montgomery, East Brunswick, NJ (US)

(73) Assignee: VEECO INSTRUMENTS INC., Plainview, NY (US)

(21) Appl. No.: 19/052,607

(22) Filed: Feb. 13, 2025

Related U.S. Application Data
(60) Provisional application No. 63/555,738, filed on Feb. 20, 2024.

(51) Int. Cl. C23C 16/44; C23C 16/455

(52) U.S. Cl. CPC C23C 16/4404; C23C 16/45589

(57) ABSTRACT

A shutter liner for use in a chemical vapor deposition (CVD) system includes an upper portion that has a cylindrical shape and a lower portion that has an outwardly flared shape. The outwardly flared shape reduces deposition within the reaction chamber by providing an outwardly angled wall surface that occupies a horizontal gap between inner and outer liners that are contained within the reaction chamber.

### CROSS REFERENCE TO RELATED APPLICATION

The present application claims priority to and the benefit of U.S. patent application Ser. No. 63/555,738, filed Feb. 20, 2024, which is hereby expressly incorporated by reference in its entirety.

### TECHNICAL FIELD

The present technology is generally related to semiconductor fabrication technology and, more particularly to chemical vapor deposition processing and associated systems having a flared shutter liner for restricting the migration of reactants outwards from the reaction volume.

### BACKGROUND

Certain processes for fabrication of semiconductors can require a complex process for growing epitaxial layers to create multilayer semiconductor structures for use in fabrication of high-performance devices, such as light emitting diodes (LEDs), laser diodes, optical detectors, power electronics, and field effect transistors. In this process, the epitaxial layers are grown through a general process called chemical vapor deposition (CVD). One type of CVD process is called metal organic chemical vapor deposition (MOCVD). In MOCVD, reactant gases are introduced into a reactor chamber within a controlled environment that enables the reactant gas to react on a substrate (commonly referred to as a “wafer”) to grow thin epitaxial layers.

During epitaxial layer growth, several process parameters are controlled, such as temperature, pressure, and gas flow rate, to achieve desired quality in the epitaxial layers. Different layers are grown using different materials and process parameters. A suitable substrate for the reaction can be in the form of a wafer having metallic, semiconducting, and/or insulating properties.

In a rotating disk reactor architecture-based CVD process chamber, one or more wafers are positioned within a rapidly rotating carousel, commonly referred to as a “wafer carrier,” so that the top surface of each wafer is exposed, thereby providing a uniform exposure of the top surface of the wafer to the atmosphere within the reactor chamber for the deposition of semiconductor materials. The wafer carriers are typically machined out of a highly thermally conductive material such as graphite and are often coated with a protective layer of a material such as silicon carbide or tantalum carbide. Each wafer carrier has a set of circular indentations, or pockets, in its top surface in which individual wafers are placed. While the wafer carrier is rotated, the reactant gases are introduced into the chamber from a gas distribution device, positioned upstream of the wafer carrier. The flowing gases pass downstream toward the wafer carrier and wafers, desirably in a laminar flow.

Traditionally, reactor system design utilizes a cylindrical shutter that has a large horizontal gap on the outside to a reactor jar (outer housing). While the flow is directed downwards and to the exhaust, reactants can escape (through diffusion, back-streaming, etc.) in through this large horizontal gap and out to the periphery of the reactor. These reactants can then produce particulate matter through gas flow recirculation, condensation, etc., and produce defects in many locations in the reactor (e.g., within the passthrough, along reactor walls, etc.) that can be transferred to the surface of the wafer. Defects on the wafer can significantly reduce device yield. There is therefore a need to reduce the amount of reactants and particulate matter that can penetrate into the horizontal gap.

### SUMMARY

The present disclosure provides a shutter liner that overcomes the deficiencies associated with traditional shutter liners and in particular, the shape of the shutter liner greatly reduces deposition growth within the horizontal gap.

More specifically, a shutter liner for use in a chemical vapor deposition (CVD) system comprises an upper portion that has a cylindrical shape and a lower portion that has an outwardly flared shape. The outwardly flared shape reduces the deposition by providing an outwardly angled wall surface that occupies the horizontal gap between the inner and outer liners. The flared shape maintains a desired radial dimension in the upper portion, while providing the dimension in the lower portion for the desired effect.

The chemical vapor deposition (CVD) system thus includes a reaction chamber and a plurality of walls including an outer liner and an inner liner that is concentric to and located radially inward of the outer liner. A first annular space is defined between the outer liner and the inner liner. The shutter liner is disposed between the outer liner and the inner liner and is movable between a raised position and a lower position. The shutter liner includes an upper portion that has a cylindrical shape and a lower portion that has an outwardly flared shape.

The raised position of the shutter liner comprises an operating position and the lowered position comprises a non-operating position that allows for insertion and removal of a wafer carrier from the reaction chamber.

### BRIEF DESCRIPTION OF THE DRAWING FIGURES

The disclosure can be more completely understood in consideration of the following detailed description of various embodiments of the disclosure, in connection with the accompanying drawings, in which:

FIG. 1 is a partial cross-sectional view of a CVD system with a flared shutter liner being shown in a raised position;

FIG. 2 is a partial cross-sectional view of the CVD system with the flared shutter liner being shown in a lowered position;

FIG. 3 is a close-up of the flared shutter liner in relation to the outer liner and inner liner;

FIG. 4 is a top and side perspective view of the flared shutter liner; and

FIG. 5 is a side elevation view of the flared shutter liner.

While embodiments of the disclosure are amenable to various modifications and alternative forms, specifics thereof shown by way of example in the drawings will be described in detail. It should be understood, however, that the intention is not to limit the disclosure to the particular embodiments described. On the contrary, the intention is to cover all modifications, equivalents, and alternatives falling within the spirit and scope of the subject matter as defined by the claims.

### DETAILED DESCRIPTION OF CERTAIN EMBODIMENTS

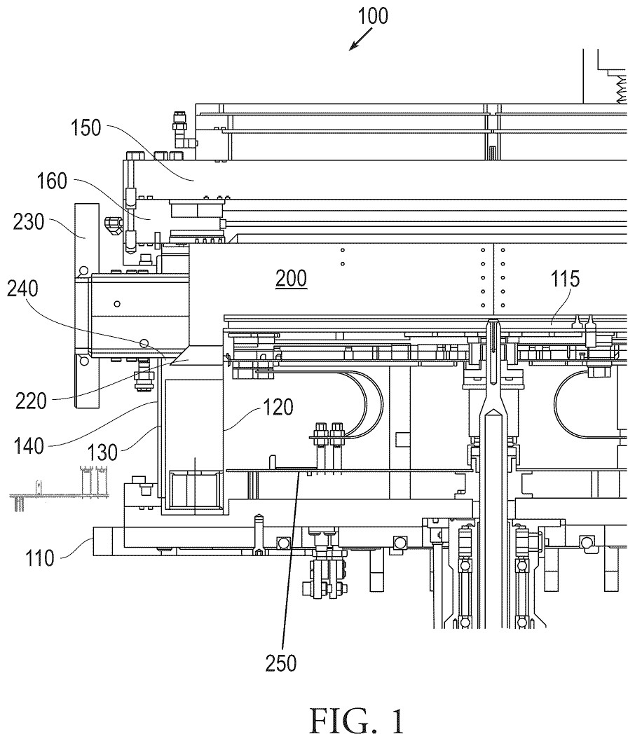

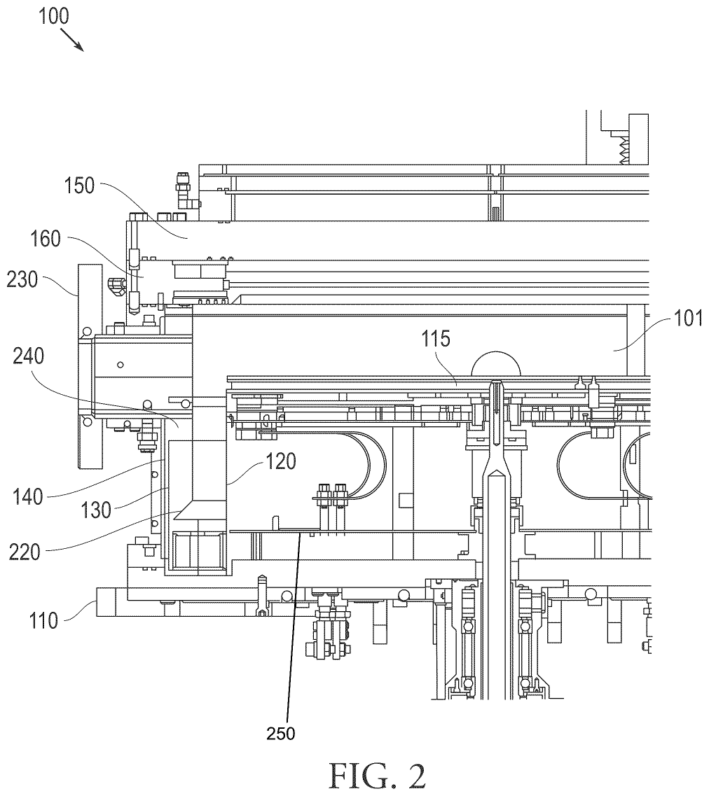

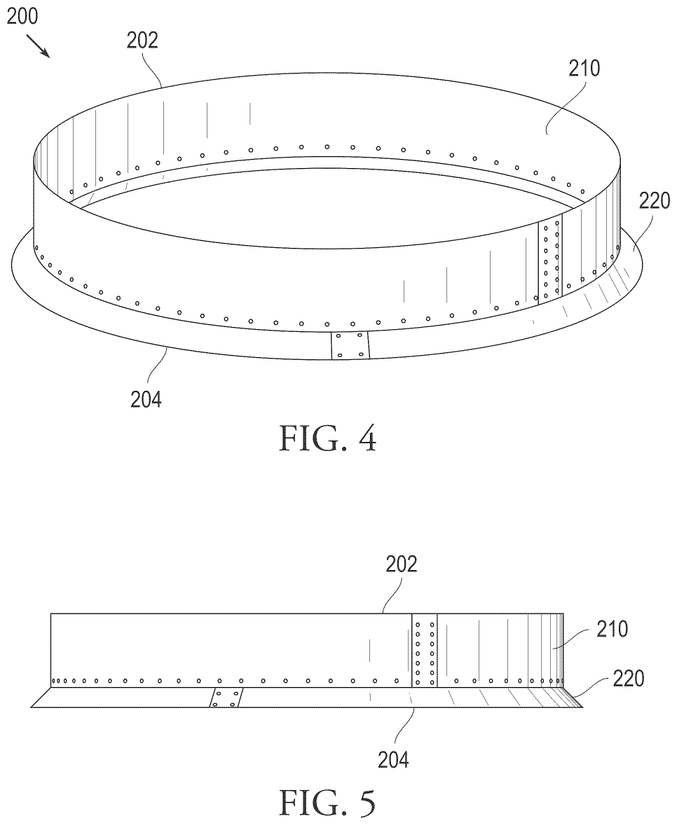

Referring to FIGS. 1-5, a chemical vapor deposition (CVD) system 100 is illustrated and includes a reaction chamber 101 (occasionally referred to herein as a “process chamber” or “reactor”), configured to define a process environment space. The reactor region of the system 100 is typically formed of vacuum-grade stainless steel or other suitable metal. The reaction chamber 101 is typically defined by a cylindrical wall with an upper end and a lower end remote therefrom. FIGS. 1-2 are partial views of the system 100 that depict one half of the system 100 to illustrate the teachings of the present disclosure.

The system includes 100 a baseplate 110 that represents the bottom of the system 100. The baseplate 110 has a number of through holes that permit passage of certain components, such as the drive shaft that rotates a wafer carrier 115, etc. As is known, the wafer carrier 115 receives one or more wafers for processing thereof.

### Multiple Liners

Between the wafer carrier 115 and the baseplate 110 there are different components that define a wall structure of the system 100. For example and as described herein, there can be several liners as well as a jar structure. More specifically, to prevent unwanted reactions with the chamber body (reaction chamber 101), liners are utilized to shield some of the metallic chamber components from the processing region. In the illustrated embodiment, the system 100 includes multiple liners 120, 130 that shield the processing volume (reaction chamber 101) from metallic walls, that surround the processing volume (reaction chamber 101). The metallic walls can include a reactor jar (weldment), generally indicated at 140, and the multiple liners 120, 130 are located radially inward from the reactor jar 140. The multiple liners 120, 130 and reactor jar 140 are concentric with one another, with the liner 120 comprising an inner liner 120 and the liner 130 comprising an outer liner 130. These three structures 120, 130, 140 can be annular shaped, with the inner liner 120 being spaced a first distance from the outer liner 130. The inner liner 120 is at a location proximate to (adjacent the wafer carrier 115 and/or related processing equipment).

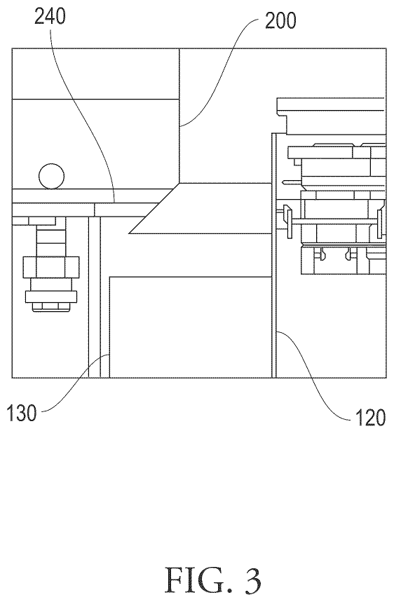

FIG. 3 is a close-up view of the top end regions of these three structures 120, 130, 140. In one embodiment, the inner liner 120 has a height greater than the heights of the outer liner 130 and the reactor jar 140 and the outer liner 130 can have a height less than the height of the reactor jar 140.

### Flow Flange

A flow flange 150 is provided to introduce reactant gases into the reaction chamber 101 at a certain prescribed location. The flow flange 150 thus defines the flow path used to introduce the reactant gases into the reaction chamber 101. The flow range 150 is located in the upper region of the reaction chamber 101.

### Cold Plate

The reaction chamber 101 has one or more gas injectors for injecting one or more gases into the reaction chamber 101. In one embodiment, there can be a gas distribution and injector head that includes a manifold assembly, which may be formed from one plate or, more typically. a plurality of plates superposed on one another. An element 160 referred to herein as a “cold plate” or “diffuser” overlies the downstream surface of the manifold assembly. Cold plate 160 can be provided with coolant passages connected to a source of a circulating coolant Cold plate defines the downstream surface of the distribution and injector head The cold plate 160 defines a plurality of first gas inlets that define ports communicating with the interior of reaction chamber 101 It will be appreciated that other types of gas injectors can be used.

### Flared Shutter Liner

In accordance with the present embodiment, a flared shutter liner 200 that moves between a raised position (FIG. 1) and a lowered position (FIG. 2) is provided. The flared shutter liner 200 is disposed within an annular shaped space between the inner liner 120 and the outer liner 130.

The system 100 includes a number of pass-through areas which are intended to provide for movement of parts, such as the insertion and removal of a wafer carrier, etc. For example, the system 100 includes a first pass through area 230 that is located radially outward from the cold plate 160. This first pass through area 230 is the volume inside the passthrough. There is a second area 240 that is located radially outward from the flared shutter liner 200 but within the reactor jar 140. This second area 240 is configured and intended to accommodate insertion and removal of the wafer carrier 115. The second area 240 represents the volume outboard of the shutter but before the passthrough.

Traditional shutter liners do not have a flared bottom portion but instead are straight and have a cylindrical shape, as in the case of the upper portion 210. This results in a large horizontal gap (annular shaped) on the outside of the shutter to the reactor jar 140.

However, Applicant observed that this type of traditional shutter liner allows for deposition growth in and near the second area 240 as well as other areas. In particular, the flared shutter liner 200 disclosed herein is intended to prevent backstreaming into both inside the passthrough 230 and into the volume (area 240) between the shutter and the jar. Typically, heavy deposition occurs in the first pass through area 230 as well as in some areas of the second area 240.

In other words, the straight walled natured of the traditional shutter liner allows deposition growth since while the flow is directed downwards and to the exhaust, reactants can escape (through diffusion and back-streaming) in through this gap (second pass through area 240) and out to the periphery of the reactor (system 100). These reactants can then produce particulate matter through gas flow recirculation, condensation, etc., and produce defects in many locations in the reactor (passthrough, reactor walls) that can be transferred to the surface of the wafer. Large particle count and parasitic deposition within the pass-through area 240 were observed. The adverse implications of this are that deposition in and near the second pass through area 240 causes contamination with wafers during insertion and removal of the wafer carrier 115. Defects on the wafer can significantly reduce device yield.

This is not desired and therefore, there is a need to greatly reduce such deposition growth especially within the pass-through area that wafers are located during operation.

More particularly, it is an objective of the present disclosure and system 100 to prevent convection and back diffusion of species contributing to the parasitic growth to the pass-through area 240. Further, it is an objective to provide for independent control of side/pass through purges and provide for temperature control within the pass-through area 240.

The design of the flared shutter liner 200 achieves these objectives. More particularly, the flared shutter liner 200 includes a top edge 202 and an opposite bottom edge 204. The flared shutter liner 200 has an upper portion 210 that terminates at the top edge 202 and a lower portion 220 that terminates at the bottom edge 204. The upper portion 210 has a cylindrical shape, while the lower portion 220 has a flared (angled) shape. As shown, the lower portion 220 has an outward taper so as to define a flared or angled end section. The lower portion 220 thus tapers outward toward the outer liner 130 and the bottom edge 204 can be in close proximity to the outer liner 130. This results in the outer diameter of the flared shutter liner 200 being greater at the bottom edge 204 than the top edge 202. The angle of the flared lower portion 220 is less than 90 degrees and can be between 40 degrees and 60 degrees, e.g., 45 degrees (as measured relative to a ground plane (horizontal plane containing the bottom edge of liner).

In one embodiment, the angled end section (flared lower portion 220) extends from the cylindrical section (upper portion 210), keeping the overall height the same as a traditional cylindrical shaped shutter/liner. The flared section (flared lower portion 220) angles outwards and blocks a large amount of species migration into the outer reactor volume. By restricting the migration of reactants outwards from the reaction volume, the propensity of deposition is significantly reduced thereby improving defectivity.

As also shown, the height of the upper portion 210 is much greater than the height of the lower portion 220 in that the flared portion of the flared shutter liner 200 only occupies a minor section of the overall shutter liner.

It will be appreciated that the flared shutter liner 200 can be formed as a single part or can be formed of two parts. For example, when the flared shutter liner 200 is formed as two parts, the (cylindrical shaped) upper portion 210 is a formed as a first part and the (flared) lower portion 220 is formed as a second part. In one embodiment, the upper portion 210 can be formed of molybdenum and similarly, the lower portion 220 can be formed of molybdenum. Alternatively, the flared shutter liner 200 can be formed of a single piece and made of different refractory metals. Fasteners, such as rivets, can be used to attach the two parts or other techniques can be used.

The movement of the flared shutter liner 200 is achieved using conventional devices, such as a motor (not shown) that is operatively coupled to the flared shutter liner 200. For example, a stepper motor can be used to precisely move the flared shutter liner 200 between the raised and lowered positions.

As mentioned, and shown in FIGS. 1-2, the flared shutter liner 200 moves between the raised position and the lowered position. The raised position is the position of the flared shutter liner 200 that results in the flared shutter liner 200 red ng the deposition buildup in the pass-through areas, such as the pass-through area 230 and area 240. The flared shutter liner 200 in the lowered position allows for the extraction of the wafer carrier. Thus, the raised position of the flared shutter liner 200 is the normal operating position of the flared shutter liner 200, while the flared shutter liner 200 in the lowered position is a non-operating position meant to define open spaces that allow for insertion and removal of the wafer carrier into the reaction chamber 101.

The flared shutter liner 200 is thus configured and moves within the reactor to perform multiple functions. Applicant has discovered that the flared design provides improved results compared to just having say a larger traditional shutter in terms of protection against reactants and particles; but also the flared shutter liner 200 also serves and satisfies additional requirements, which drives the upper and lower configurations of the liner 200.

### EXAMPLE

Applicant observed, based on modeling, that when a traditional straight shutter liner was used in the CVD system, the deposition was 3 microns per hour (μm/hr) (within the second pass through area 240). In contrast, when the flared shutter liner 200 was used in system 100, the deposition rate was 0.25 microns per hour. This is a more than 91% reduction in the deposition rate and accordingly, far less material is deposited over the same amount of time.

### Baffle

The disclosed reactor can include a baffle assembly 250 that is illustrated in the figures, e.g., FIG. 1. The baffle assembly 250 includes an integrated reflective shield that can be made of a 304 stainless steel sheet with a mirror-like one side polished or similar reflective material. The baffle assembly 250 is disposed between the water-cooled reactor baseplate 110 and the reactor's heater assembly. The baffle assembly 250 is intended and constructed to reflect thermal radiation back up into the heater cavity allowing for faster carrier heating rates with minimized heat loses.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. § 112 (f) are not to be invoked unless the specific terms “means for” or “step for” are recited in a claim.

What is claimed is:

1. A shutter liner for use in a chemical vapor deposition (CVD) system comprising:
an upper portion that has a cylindrical shape; and
a lower portion that has an outwardly flared shape.

2. The shutter liner of claim 1, wherein the shutter liner is formed of a metal.

3. The shutter liner of claim 1, wherein the shutter liner is formed of molybdenum.

4. The shutter liner of claim 1, wherein the shutter liner comprises a single piece.

5. The shutter liner of claim 1, wherein the shutter liner comprises two pieces, with the lower portion being separate from and coupled to the upper portion.

6. The shutter liner of claim 5, wherein the two pieces are formed of the same material.

7. The shutter line of claim 1, wherein a height of the upper portion is greater than a height of the outwardly flared lower portion.

8. A chemical vapor deposition (CVD) system comprising:
a reaction chamber;
a plurality of walls including an outer liner and an inner liner that is concentric to and located radially inward of the outer liner, wherein a first annular space is defined between the outer liner and the inner liner; and
a shutter liner that is disposed within the first annular space between the outer liner and the inner liner and is movable between a raised position and a lower position, wherein the shutter liner includes an upper portion that has a cylindrical shape and a lower portion that has an outwardly flared shape.

9. The CVD system of claim 8, wherein the plurality of walls includes a reactor jar that is concentric to the outer liner and the inner liner and is located radially outward from the outer liner.

10. The CVD system of claim 8, wherein the shutter liner is formed of a metal.

11. The CVD system of claim 8, wherein the shutter liner is formed of molybdenum.

12. The CVD system of claim 8, wherein the shutter liner comprises a single piece.

13. The CVD system of claim 8, wherein the shutter liner comprises two pieces, with the lower portion being separate from and coupled to the upper portion.

14. The CVD system of claim 13, wherein the two pieces are formed of the same material.

15. The CVD system of claim 13, wherein a bottom edge of the shutter liner is in close proximity to the outer liner.

16. The CVD system of claim 8, wherein the raised position comprises an operating position of the shutter liner and the lowered position comprises a non-operating position that allows for insertion and removal of a wafer carrier from the reaction chamber.

17. The CVD system of claim 16, wherein in the lowered position a top edge of the shutter liner is disposed below the wafer carrier.

18. The CVD system of claim 16, wherein in the raised position, the lower portion of the shutter liner is disposed below the wafer carrier.

19. The CVD system of claim 8, further including a rotatable wafer carrier disposed within the reaction chamber, the inner liner being disposed radially outward from the wafer carrier.
